(19) United States
(12) Patent Application Publication
(10) Pub. No.: US 2016/0073510 A1
(43) Pub. Date: Mar. 10, 2016

(54) HOLDING DEVICE, MOUNTING DEVICE, MOUNTING METHOD, AND METHOD OF MANUFACTURING CIRCUIT BOARD DEVICE

(71) Applicant: FUJI XEROX CO., LTD., Tokyo (JP)

(72) Inventors: Shingo MORIKAWA, Mie (JP); Takeyoshi HORIUCHI, Mie (JP)

(21) Appl. No.: 14/599,041

(22) Filed: Jan. 16, 2015

(30) Foreign Application Priority Data
Sep. 10, 2014 (JP) 2014-184349

(51) Int. Cl. H05K 3/30

(52) U.S. Cl. CPC H05K 3/30

(57) ABSTRACT

Provided is a holding device including a main body on which two surfaces that come into bump-contact with two ridge lines along a top surface of an element in a longitudinal direction, in one to one correspondence, are formed and which holds the element in a state that the two surfaces come into bump-contact with the two ridge lines, and a restriction unit that is provided in the main body, comes into contact with the top surface of the element, and restricts an inclination of the element with respect to the main body to be within an inclination limit.

### CROSS-REFERENCE TO RELATED APPLICATIONS

This application is based on and claims priority under 35 USC 119 from Japanese Patent Application No. 2014-184349 filed Sep. 10, 2014.

### BACKGROUND

1. Technical Field

The present invention relates to a holding device, a mounting device, a mounting method, and a method of manufacturing a circuit board device,

### SUMMARY

According to an aspect of the invention, there is provided a holding device including:

a main body on which two surfaces that come into bump-contact with two ridge lines along a top surface of an element in a longitudinal direction, in one to one correspondence, are formed and which holds the element in a state that the two surfaces come into bump -contact with the two ridge lines; and

a restriction unit that is provided in the main body, comes into contact with the top surface of the element, and restricts an inclination of the element with respect to the main body to be within an inclination limit.

### BRIEF DESCRIPTION OF THE DRAWINGS

Exemplary embodiments of the present invention will be described in detail based on the following figures, wherein:

FIG. 1 is a perspective view illustrating a configuration of a manufacturing apparatus according to an exemplary embodiment;

FIG. 2 is a plan view illustrating a configuration of a printed circuit board device according to the exemplary embodiment;

FIG. 3 is a perspective view illustrating a collet according to the exemplary embodiment;

FIG. 4 is a side view illustrating the collet illustrated in FIG. 3;

FIG. 5 is a front view illustrating the collet illustrated in FIG. 3;

FIG. 6 is a front view illustrating a state in which a semiconductor element is inclined in a view illustrated in FIG. 5;

FIG. 7 is a front view illustrating a state in which the semiconductor element is inclined to a side opposite to that illustrated in FIG. 6;

FIG. 8 is a front view illustrating a configuration of the semiconductor element; and

FIG. 9 is a view illustrating an aspect of connecting a wire to a pad of the semiconductor element.

### DETAILED DESCRIPTION

Hereinafter, an example of an exemplary embodiment of the invention will be described based on the figures.

Manufacturing Apparatus 10

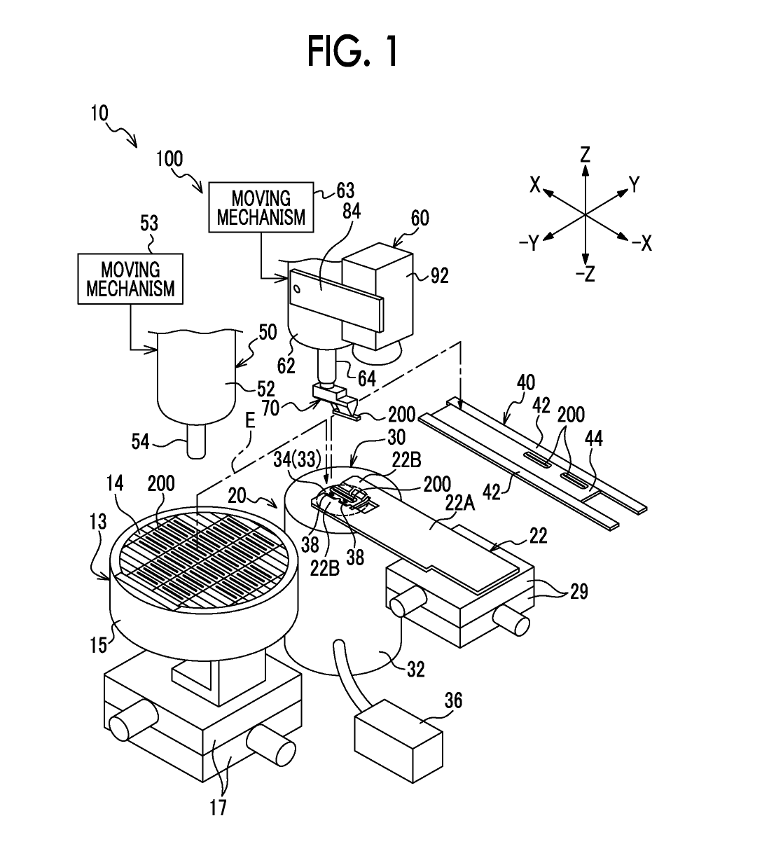

First, a configuration of a manufacturing apparatus 10 according to the exemplary embodiment is described. FIG. 1 is a perspective view illustrating a configuration of the manufacturing apparatus 10. An X (−X) direction, a Y (−Y) direction, and a Z (−Z) direction to foe described later represent coordinate axes orthogonal to one another and the X direction, the −X direction, the Y direction, the −Y direction, the Z direction (upward) and the −Z direction (downward) are directions of arrows illustrated in the figures. In addition, except for a case where a specific description is provided, “X direction” means “X direction or −X direction”, “Y direction” means “Y direction or −Y direction”, and “Z direction” means “Z direction or −Z direction”. In addition, a mark that has “x” inside “O” in the figures means an arrow pointing from the front surface of paper toward the rear surface, and a mark that has “•” inside “O” in the figures means an arrow pointing from the rear surface of paper toward the front surface. In addition, a dimensional ratio of members illustrated in the FIGS. in the X direction, Y direction, or Z direction, and a dimensional ratio between the members illustrated in the figures in the X direction, Y direction, or Z direction are not limited to a dimensional ratio illustrated in the figures.

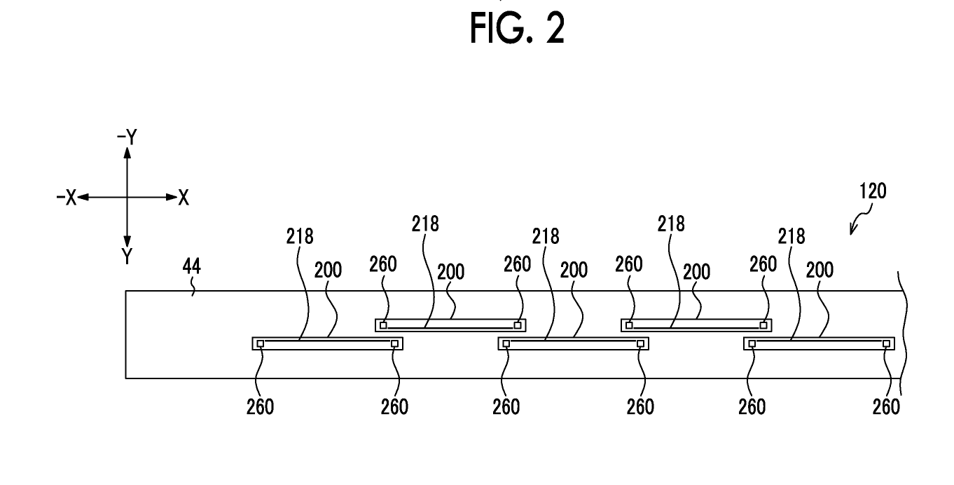

The manufacturing apparatus 10 manufactures a printed circuit board device 120 (see FIG. 2) as an example of a circuit board device. Specifically, as illustrated in FIG. 1, the manufacturing apparatus 10 includes a supplying unit 13 that supplies a semiconductor element 200 as an example of an element, an element positioning device 20 that positions the semiconductor element 200, and a circuit board positioning device 40 that positions a printed circuit board 44 as an example of the circuit board. In addition, the manufacturing apparatus 10 includes a transport device 50 that transports the semiconductor element 200 from the supplying unit 13 to the element positioning device 20, and a transport device 60 that transports the semiconductor element 200 positioned by the element positioning device 20 to the printed circuit board 44 positioned by the circuit board positioning device 40.

In the manufacturing apparatus 10, amounting device 100 that mounts the semiconductor element 200 onto the printed circuit board 44 includes the element positioning device 20, the circuit board positioning device 40, and the transport device 60.

Printed Circuit Board Device 120

As illustrated in FIG. 2, the printed circuit board device 120 that is manufactured by the manufacturing apparatus 10 includes the printed, circuit board 44 as an example of the circuit board, and the semiconductor elements 200 disposed (mounted) on the printed circuit board 44. The printed circuit board 44 is formed, for example, into a plate shape which is long in the X direction. The semiconductor elements 200 are disposed in a zigzag line, for example, along the longitudinal direction of the printed circuit board 44.

Semiconductor Element 200

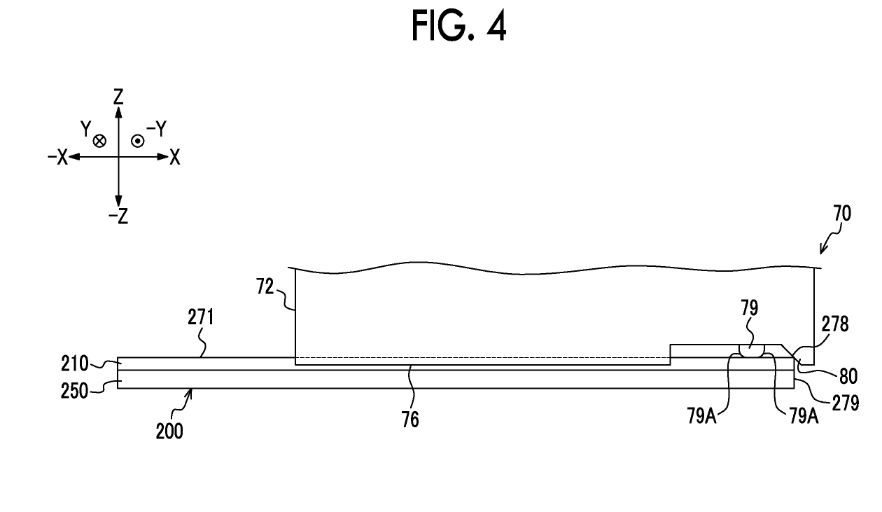

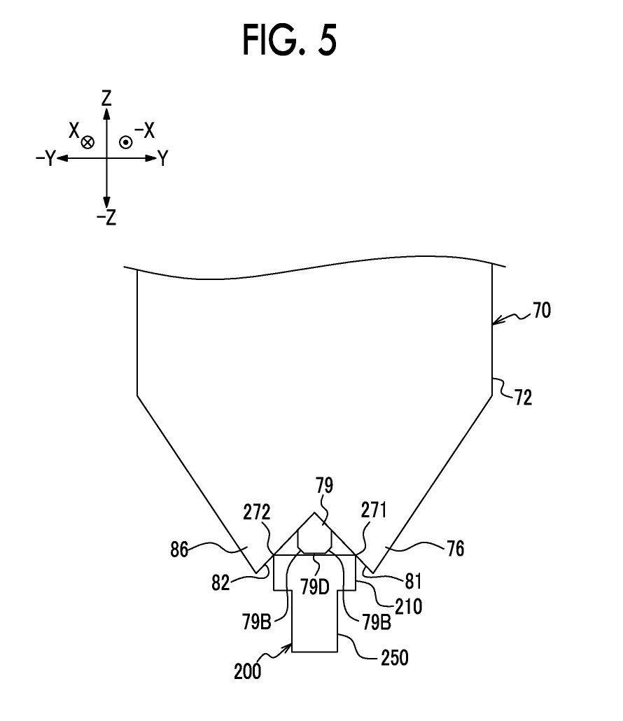

As illustrated in FIG. 4, as the semiconductor element 200, for example, a light-emitting element (for example, LED chip) which is long in the X direction is used. As illustrated in FIG. 5, the semiconductor element 200 has a shape (cross-sectional shape) of a T when viewed in the longitudinal direction (X direction). The semi conductor element 200 includes a main body section 210 that configures a horizontal bar section of the T shape and a leg section 250 that configures a vertical section of the T shape. A first ridge line 271 (corner) and a second ridge line 272 (corner) are formed on the top surface (front surface) of the main body section 210 along the longitudinal direction (X direction).

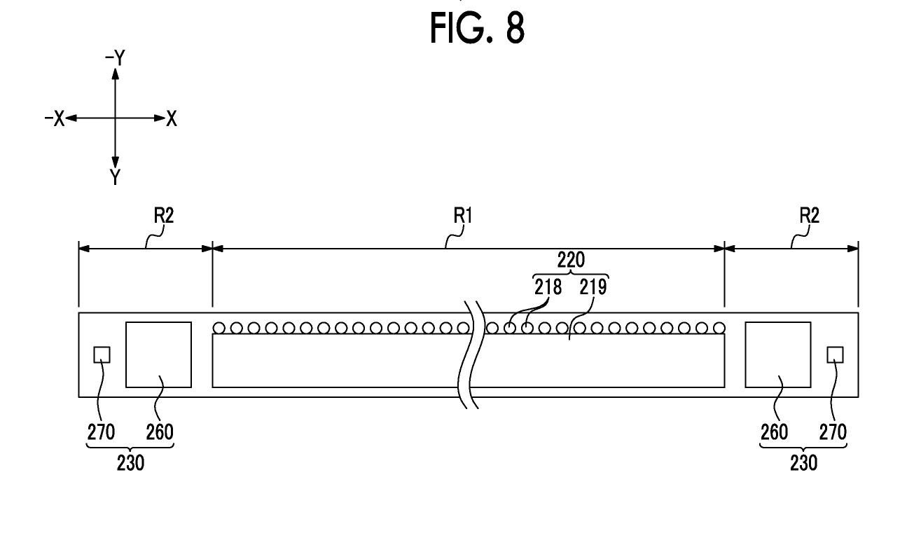

In addition, as illustrated in FIG. 8, a functioning section 220 such as plural light-emitting points 218 or a circuit pattern 219 which are disposed along the X direction is provided, on the top surface (front surface) of the main body section 210. The functioning section 220 is disposed on the side of the center of the semiconductor element 200 in the longitudinal direction on the top surface of the main body section 210. The functioning section 220 is a section of which a function that is needed may not be performed in a case of being damaged due to a contact load due to an external factor.

Further, non-functioning sections 230 (sections other than the functioning section 220) including a recognition mark 270 that is recognized by an imaging camera 92 to be described later, a pad 260 (connection section) that is connected electrically to a wire (gold wire), and the like, are provided,

According to the exemplary embodiment, a disposition region R1 where the functioning section 220 is disposed is positioned on the side of the center of the semiconductor element 200 in the longitudinal direction. Disposition regions R2 where the non-functioning sections 230 are disposed are positioned on both end sides of the semiconductor element 200 in the longitudinal direction.

The semiconductor element 200 has, for example, a length (length in the X direction) of 6 mm, a height (length in the Z direction) of 300 μm, a width of the main body section 210 (length in the Y direction) of 115 μm, and a width of the leg section 250 (length in the Y direction) of 90 μm. The size of the semiconductor element 200 is not limited to the size described above. In addition, in FIG. 1, the semiconductor element 200 is illustrated in a simplified manner.

Supplying Unit 13

As illustrated in FIG. 1, the supplying unit 13 includes a holding unit 15 that holds a wafer 14 and a moving mechanism 17 that causes the holding unit 15 to move in the X direction and the Y direction. In the supplying unit 13, the wafer 14 which is held by the holding unit 15 is cut, which causes plural semiconductor elements 200 to be cut out from the wafer 14. In addition, in the supplying unit 13, the moving mechanism 17 causes the holding unit 15 to move in the X direction and the Y direction, which causes the semiconductor element 200 which is a mounting target to be positioned at a predetermined pickup position by the transport device 50.

Transport Device 50

As illustrated in FIG. 1, the transport device 50 includes a suction unit 52 of which a suction nozzle 54 sucks the semiconductor element 200 and a moving mechanism 53 that causes the suction unit 52 to move. In the transport device 50, the suction nozzle 54 of the suction unit 52 sucks the semiconductor element 200 which is positioned at a pickup position on the supplying unit 13 and the suction nozzle 54 holds the semiconductor element 200. In the transport device 50, the suction unit 52 is moved in a direction of arrow E by the moving mechanism 53 in a state where the suction nozzle 54 holds the semiconductor element 200, which causes the semiconductor element 200 to be transported onto a plate 34 of a positioning mount 30 to be described later. As the moving mechanism 53 of the transport device 50, for example, a triaxial robot which is capable of moving in the X direction, the Y direction, and the Z direction is used.

Element Positioning Device 20

As illustrated in FIG. 1, the element positioning device 20 includes the positioning mount 30 as a mount on which the semiconductor element 200 is mounted, a positioning member 22 that positions the semiconductor element 200 temporarily disposed on the positioning mount 30 to a predetermined position, and a moving mechanism 29 that causes the positioning member 22 to move in the X direction and the Y direction.

The positioning mount 30 includes a cylindrical section 32 having an opening 33 on the top, the plate 34 provided on the opening 33 of the cylindrical section 32, and a suction device 36 that sucks air from an internal space of the cylindrical section 32 and makes the internal space have negative pressure. Plural suction holes 38 are formed on the plate 34. The plural suction holes 38 penetrate the plate 34 and communicate with the inner space of the cylindrical section 32.

As illustrated in FIG. 1, the positioning member 22 has a plate-like shape and includes a main body section 22A and a pair of claws 22B that extend from the main body section 22A in the X direction. The pair of claws 22B are provided to be spaced from each other in the Y direction such that the semiconductor element 200 may be disposed therebetween. The positioning member 22 has a U shape in a plan view (view in the −Z direction) that is formed by the pair of claws 22B and the main body section 22A. The positioning member 22 moves by maintaining a state in which the positioning member 22 is not in contact with the plate 34 so as not to be affected by resistance of moving due to adsorption to the plate 34.

In the positioning member 22, the side surfaces of the semiconductor element 200 are brought into bump-contact with the claws 22B such that the semiconductor element 200 is caused to move and the semiconductor element 200 is positioned at the predetermined position.

A groove (not illustrated) which opens on the undersurface is formed in each claw 22B, the suction force through the suction holes 38 acts on the side surfaces of the semiconductor element 200 through the groove, and the side surfaces of the semiconductor element 200 brought into bump-contact with the claws 22B are sucked by the claws 22B.

In addition, according to the exemplary embodiment, one of the pair of claws 22B is selected to position the semiconductor element 200. The positioning member 22 may have a configuration in which one of the pair of claws 22B is not included.

Circuit Board Positioning Device 40

As illustrated in FIG. 1, the circuit board positioning device 40 includes a pair of transport members (for example, conveyor) 42 which transport the printed circuit board 44 in the X direction. The pair of transport members 42 are disposed to be spaced from each other in the Y direction such that the printed circuit board 44 is put therebetween.

In the circuit board positioning device 40, the printed circuit board 44 put between the pair of transport members 42 is positioned in the X direction, the Y direction, and the Z direction with respect to the pair of transport members 42. The pair of transport members 42 transport the printed circuit board 44 in the X direction, and thereby the printed circuit board 44 is caused to move in the X direction in a state of being positioned in the Y direction relative to a collet 70 to be described later.

The circuit board positioning device 40 includes an applying device (not illustrated) such as a dispenser for applying an adhesive (not illustrated) such as an epoxy-based adhesive containing silver (Ag) at a position on the printed circuit board 44 where the semiconductor element 200 is disposed.

Transport Device 60

As illustrated in FIG. 1, the transport device 60 includes the collet 70 as an example of a holding device that holds the semiconductor element 200 and a suction unit 62 on which the collet 70 is mounted and which generates a suction force for the collet 70 to hold the semiconductor element 200.

Further, the transport device 60 includes the imaging camera 92 that images the recognition mark 270 of the semiconductor element 200, a support 84 that supports the suction unit 62 and the imaging camera 92, and a moving mechanism 63 that causes the collet 70 and the imaging camera 92 to move relative to the printed circuit board 44. Specifically, the suction unit 62 has a suction nozzle 64 on which the collet 70 is mounted. A connection section 74 of the collet 70, which will be described later, is connected to the suction nozzle 64.

The moving mechanism 63 causes the suction unit 62 and the imaging camera 92 to move in the Y direction and thereby to cause the collet 70 and the imaging camera 92 to move in the Y direction relative to the printed circuit board 44. That is, according to the exemplary embodiment, the collet 70 and the imaging camera 92 are moved in the Y direction by the moving mechanism 63, and the printed circuit board 44 is moved in the X direction by the transport members 42 of the circuit board positioning device 40, which causes the collet 70 and the imaging camera 92 to move in the X direction and the Y direction relative to the printed circuit board 44.

In addition, the moving mechanism 63 causes the suction unit 62 to move in the vertical direction (Z direction), which causes the collet 70 to move in the vertical direction (Z direction) relative to the printed circuit board 44, According to the exemplary embodiment, after causing the collet 70 to move in the X direction and the Y direction relative to the printed circuit board 44, the collet 70 is caused to be lowered downward (−Z direction), which causes the semiconductor element 200 held by the collet 70 to be disposed (mounted) on the printed circuit board 44.

The position of the semiconductor element 200 in the X direction and the Y direction when the semiconductor element 200 is mounted on the printed circuit board 44 is determined with the position of the recognition mark 270 imaged by the imaging camera 92 as a reference. For example, as the moving mechanism 63, a biaxial robot that is capable of moving in the Y direction and Z direction is used.

Collet 70

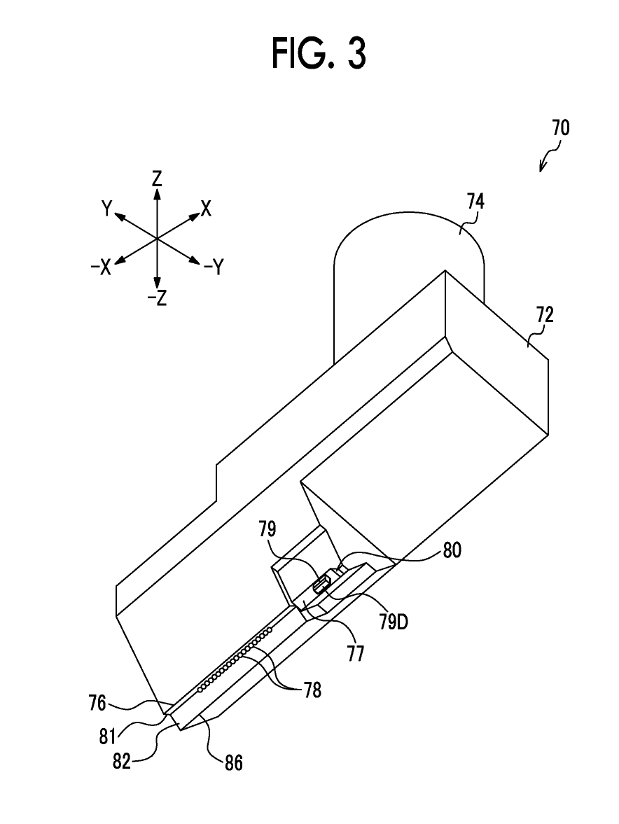

As illustrated in FIG. 3, the collet 70 (example of holding device) includes a collet main body 72 as an example of a main body and the connection section 74 that is connected to the suction nozzle 64 (see FIG. 1) of the suction unit 62. As illustrated in FIG. 5, the collet main body 72 includes a bump-contact portion 76 that has a first surface 81 which comes into bump-contact with the first ridge line 271 of the semiconductor element 200 and a bump-contact portion 86 that has a second surface 82 which comes into bump-contact with the second ridge line 272 of the semiconductor element 200. Further, as illustrated in FIG. 4, the collet main body 72 has a bump-contact claw 80 that comes into bump-contact with a ridge line 278 (corner) of the semiconductor element 200 on the X direction side. The bump-contact claw 80 may be brought into bump-contact with an end surface 279 of the semiconductor element 200 on the X direction side.

As illustrated in FIG. 3, the connection section 74 is formed to be cylindrical and is inserted into the cylindrical suction nozzle 64 (see FIG. 1) and thereby is connected to the suction nozzle 64. As illustrated in FIG. 3, plural suction ports 78 are formed between the second surface 82 and the first surface 81. The suction ports 78 communicate with the suction nozzle 64 through passages (not illustrated) which are formed inside the collet main body 72 and inside the connection section 74.

In the collet 70, the second ridge line 272 on the top surface of the semiconductor element 200 comes into bump-contact with the second surface 82 and the first ridge line 271 on the top surface of the semiconductor element 200 comes into bump-contact with the first surface 81, which causes the semiconductor element 200 to be positioned in the Y direction and the Z direction. In addition, in the collet 70, the ridge line 278 of the semiconductor element 200 on the X direction side comes into bump-contact with the bump-contact claw 80, which causes the semiconductor element 200 to be positioned in the X direction.

Further, in the collet 70, the semiconductor element 200 is sucked through the suction ports 78 by the suction unit 62 (see FIG. 1) and the semiconductor element 200 which is in a state of being positioned in the Y direction, the Z direction, and the X direction is held to the collet main body 72. In addition, in the collet 70, the suction by the suction unit 62 may be stopped, which causes the state of the semiconductor element 200 being held by the collet 70 to be released.

Here, as illustrated in FIGS. 3 to 5, the collet 70 according to the exemplary embodiment has a restriction unit 79 that comes into contact with the top surface of the semiconductor element 200 and restricts an inclination of the semiconductor element 200 with respect to the collet main body 72 to be within an inclination limit. The inclination limit of the semiconductor element 200 is a predetermined limit which is allowable in design.

The restriction unit 70 is a substantially rectangular parallelepiped. As illustrated in FIG. 4, a lower end 79A of the restriction unit 79 in the −X direction and the X direction is rounded into a round shape R when viewed in the Y direction. The lower end 79A may be chamfered when viewed in the Y direction. Further, as illustrated in FIG. 5, a lower end 79B of the restriction unit 79 is chamfered in the −Y direction and the Y direction when viewed in the X direction. The lower end 79B may be rounded into a round shape R when viewed in the X direction.

As illustrated in FIG. 4, the restriction unit 79 is disposed between the bump-contact portion 76 (bump-contact portion 86) and the bump-contact claw 80 in the collet main body 72. Specifically, as illustrated in FIG. 3, the restriction unit 79 protrudes downward to have a convex shape from an undersurface 77 in the collet main body 72 which faces downward (−Z direction) disposed between the bump-contact portion 76 (bump-contact portion 86) and the bump-contact claw 80. Further, specifically, the restriction unit 79 is provided at a position (position in the X direction) which is in contact with or facing the disposition regions R2 on the X direction side, where the non-functioning sections 230 (see FIG. 8) are disposed, on the fop surface of the semiconductor element 200 which is in a state of being held.

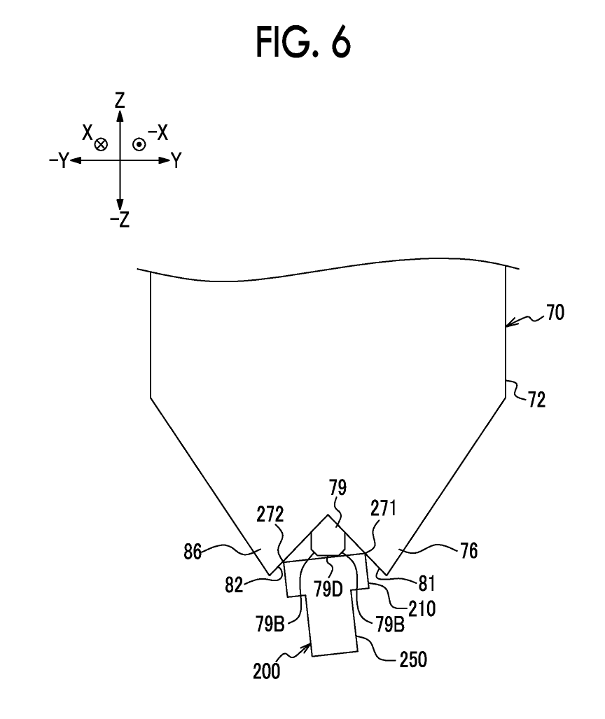

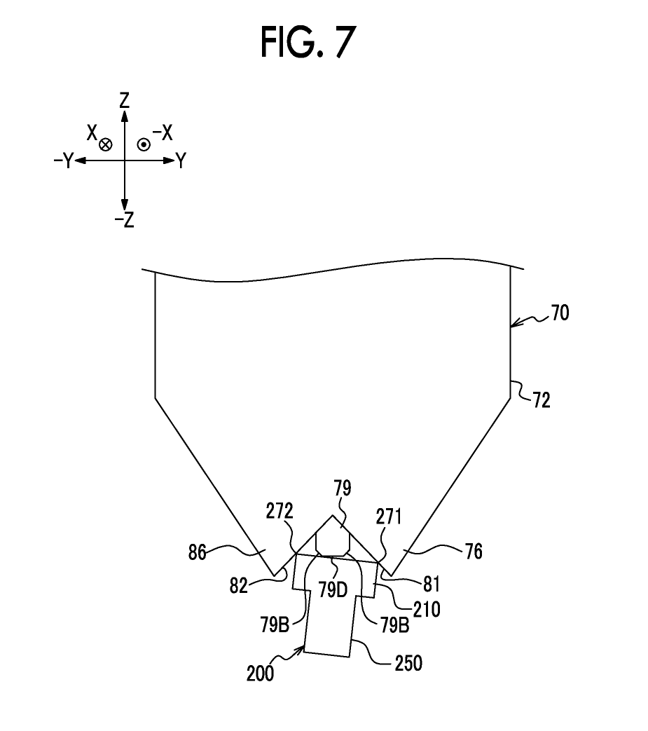

In addition, the restriction unit 79 is set to have a position (position in Y direction), a size and a shape such that, as illustrated in FIGS. 6 and 7, the restriction unit 79 comes into contact with the top surface of the semiconductor element 200 in a case where the inclination of the semiconductor element 200 with respect to the collet main body 72 is the inclination limit and, as illustrated in FIG. 5, the restriction unit 79 is separated from the top surface of the semiconductor element 200 in a case where the inclination of the semiconductor element 200 with respect to the collet main body 72 is less than the inclination limit.

That is, an undersurface 79D of the restriction unit 79 is positioned above a position (position illustrated in FIG. 5) where the first ridge line 271 and the second ridge line 272 of the semiconductor element 200 come into contact with the collet main body 72 (first surface 81 and second surface 82), in an appropriate posture with respect to the collet main body 72 (state in which the semiconductor element 200 is not inclined with respect to the collet main body 72).

Method of Manufacturing Printed Circuit Board Device 120

In a method of manufacturing the printed circuit board device 120 according to the exemplary embodiment, as illustrated in FIG. 1, first, in the supplying unit 13, the moving mechanism 17 causes the holding unit 15 to move in the X direction and the Y direction, which causes the semiconductor element 200 of the mounting target to be positioned at the predetermined pickup position (position adjusting process).

Next, the semiconductor element 200 positioned at the pickup position of the supplying unit 13 is transported over the plate 34 of the positioning mount 30 by the transport device 50 and the semiconductor element 200 is temporarily positioned over the plate 34 (temporary positioning process).

Next, the claws 22B of the positioning member 22 come into bump-contact with the side surfaces of the semiconductor element 200 temporarily positioned over the plate 34 and the semiconductor element 200 is moved to a predetermined position over the plate 34 to be positioned (element positioning process).

Next, in the circuit board positioning device 40, the pair of transport members 42 positions the printed circuit board 44 (circuit board positioning process). The process of positioning the circuit board does not have to be performed after the element positioning process, and may be performed before or at the same time as the element positioning process.

Next, the adhesive is applied on the printed circuit board 44 positioned in the circuit board positioning device 40 (application process). The application process may be changed to be performed during a holding process to be described later such that the adhesive is applied to the semiconductor element 200 held by the collet 70.

Next, the semiconductor element 200 positioned over the plate 34 is held by the collet 70 of the transport device 60 (holding process). Specifically, the holding process is performed as follows.

That is, first, the collet 70 is lowered to the positioned semiconductor element 200, the first surface 81 of the collet 70 comes into bump-contact with the first ridge line 271 of the semiconductor element 200, and the second surface 82 of the collet 70 comes into bump-contact with the second ridge line 272 of the semiconductor element 200. At this time, the bump-contact claw 80 of the collet 70 is also in a state of coming into bump-contact with the ridge line 278 of the semiconductor element 200. Thus, the semiconductor element 200 is positioned in the Y direction, the Z direction, and the X direction with respect to the collet 70.

The suction unit 62 of the transport device 60 starts suction. Thus, the semiconductor element 200 positioned by the second surface 82, the first surface 81, and the bump-contact claw 80 in the Y direction, the Z direction and the X direction, is held by the collet 70.

Next, the semiconductor element 200 held by the collet 70 is mounted on the printed circuit board 44 positioned in the circuit board positioning process (mounting process).

In the manufacturing process, the position adjusting process, the temporary positioning process, the element positioning process, the application process, the holding process, and the mounting process are performed in accordance with the number of the semiconductor elements 200 of the printed circuit board device 120 and, in the mounting process, the plural semiconductor elements 200 are disposed on the printed circuit board 44, for example, in a zigzag line (see FIG. 2). Next, the adhesive is solidified (solidification process). Specifically, for example, the adhesive is heated, for example, for one to two hours at a temperature range of 110° C. to 120° C. such that the adhesive is solidified. A pad (not illustrated) on the printed circuit board 44 connected electrically to a drive circuit that drives the semiconductor element 200 as a light-emitting element is connected electrically to the pad 260 of each of the semiconductor elements 200 through a wire (gold wire) by a wire-bonding method. Thus, the printed circuit board device is manufactured.

According to the exemplary embodiment, the method of mounting the semiconductor element 200 on the printed circuit board 44 includes, as described above, at least the application process and the mounting process.

Action of Exemplary Embodiment

According to the exemplary embodiment, as described above, the semiconductor element 200 held by the collet 70 is mounted on the printed circuit board 44 on which the adhesive is applied. At this time, for example, in a case where the adhesive applied on the printed circuit board 44 is displaced from the predetermined position or in a case where a large amount of the adhesive is partially applied, a biasing force acts on the semiconductor element 200 and the semiconductor element 200 is inclined in some cases.

In contrast, according to the exemplary embodiment, as illustrated in FIGS. 6 and 7, when the semiconductor element 200 is inclined with respect to the collet main body 72, the restriction unit 79 comes into contact with the top surface of the semiconductor element 200 and restricts the inclination of the semiconductor element 200 to being within the inclination limit. The inclination of the semiconductor element 200 that exceeds the inclination limit is suppressed, compared to the case where the restriction unit 79 is not provided.

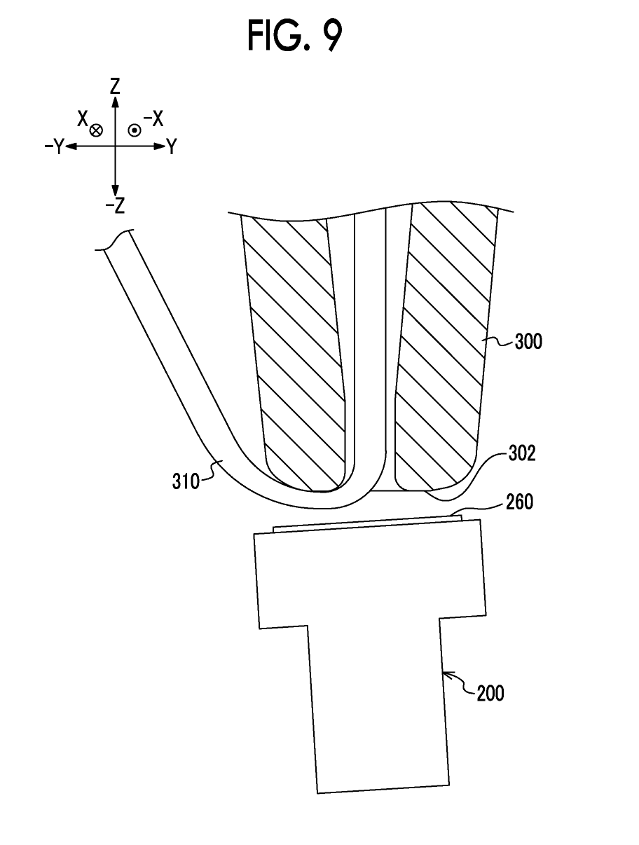

Thus, since the inclination of the semiconductor element 200 is suppressed, connection failure is prevented when a wire is connected to the pad 260 of the semiconductor element 200 by the wire-bonding method. Here, as illustrated in FIG. 9, in the wire-bonding method, a wire 310 pulled out from a capillary 300 is heated and melted and the melted portion of the wire 310 is pressed and connected to the pad 260 on an annular lower end 302 of the capillary 300. Therefore, as illustrated in FIG. 9, when the semiconductor element 200 is inclined, a pressing force becomes high at a portion in the vicinity of the pad (portion on the Y direction side in FIG. 9) which is close to the pad 260 of the annular lower end 302 of the capillary 300 and the pressing force is decreased at a separated portion (portion on the −Y direction side in FIG. 9) which is spaced from the pad 260. Accordingly, in the separated portion, the connection failure of the wire 310 due to a lack of the pressure occurs in some cases and, in the portion in the vicinity of the pad, the wire 310 is cut off due to excessive pressure and connection failure occurs in some cases.

In addition, according to the exemplary embodiment, the restriction unit 79 comes into contact with the top surface of the semiconductor element 200 in a case where the inclination of the semiconductor element 200 with respect to the collet main body 72 reaches the inclination limit. As illustrated in FIG. 5, in a case where the inclination of the semiconductor element 200 with respect to the collet main body 72 is less than the inclination limit, the restriction unit 79 is separated from the top surface of the semiconductor element 200. Thus, damage to the semiconductor element 200 is prevented, compared to a case where the restriction unit 79 comes into contact with the top surface of the semiconductor element 200 regardless of a degree of the inclination of the semiconductor element 200 with respect to the collet main body 72.

In addition, according to the exemplary embodiment, the restriction unit 79 comes into contact with the disposition regions R2 on the X direction side, on which the non-functioning sections 230 are disposed, on the top surface of the semiconductor element 200. Thus, damage to the functioning section 220 of the semiconductor element 200 is prevented, compared to a case where the restriction unit 79 comes into contact with the disposition region R1 where the functioning section 220 of the semiconductor element 200 is disposed.

As described above, according to the exemplary embodiment, mounting failure is prevented, in which the semiconductor element 200 is inclined and is mounted on the printed, circuit board 44. Therefore, a yield of printed circuit board devices to be manufactured is improved.

Modification Example

According to the exemplary embodiment, the semiconductor element 200 has the T-shaped cross section; however, the shape is not limited thereto, and may be, for example, a rectangular cross section.

In addition, according to the exemplary embodiment, the undersurface 79D of the restriction unit 79 is positioned above a position where the first ridge line 271 and the second ridge line 272 of the semiconductor element 200 come into contact with the collet main body 72 (first surface 81 and second surface 82), in an appropriate posture with respect to the collet main body 72; however, the posture is not limited thereto. For example, the undersurface 79D of the restriction unit 79 may be disposed at the same elevation as the contact position. That is, the restriction unit 79 may restrict the inclination of the semiconductor element 200 such that the semiconductor element 200 is not inclined from the appropriate posture.

In addition, according to the exemplary embodiment, the restriction unit 79 is in contact with the disposition region R2, on which the non-functioning sections 230 are disposed, on the top surface of the semiconductor element 200; however, the contact position is not limited thereto. The restriction unit 79 may come into contact with the disposition region R1 on which the functioning section 220 is disposed.

The invention is not limited to the above exemplary embodiments, and it is possible to perform various modifications, changes, and improvements. For example, the modification examples described above may appropriately combine plural modification examples.

The invention may be understood as follows.

A holding device includes: a first surface that comes into bump-contact with a first ridge line along a top surface of an element in a longitudinal direction; a second surface that comes into bump-contact with a second ridge line along the first ridge line on the top surface; a main body on which the first surface and the second surface are formed and which holds the element in a state where the first surface comes into bump-contact with the first ridge line and the second surface comes into bump-contact with the second ridge line; and a restriction unit that is provided in the main body, comes into contact with the top surface of the element, and restricts an inclination of the element with respect to the main body to be within an inclination limit.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A holding device comprising:
a main body on which two surfaces that come into bump-contact with two ridge lines along a top surface of an element in a longitudinal direction, in one to one correspondence, are formed and which holds the element in a state that the two surfaces come into bump-contact with the two ridge lines; and
a restriction unit that is provided in the main body, comes into contact with the top surface of the element, and restricts an inclination of the element with respect to the main body to be within an inclination limit.

2. The holding device according to claim 1,
wherein the restriction unit comes into contact with the top surface of the element in a case where the inclination of the element with respect to the main body is the inclination limit, and is separated from the top surface of the element in a case where the inclination of the element with respect to the main body is less than the inclination limit.

3. The holding device according to claim 1,
wherein the restriction unit comes into contact with a region on the top surface of the element other than a region where a functioning section is disposed.

4. The holding device according to claim 2,
wherein the restriction unit comes into contact with a region on the top surface of the element other than a region where a functioning section is disposed.

5. A mounting device comprising:
the holding device according to claim 1; and
a moving mechanism that causes the holding device to move and mounts the element on a circuit board.

6. A mounting method comprising:
applying an adhesive on an element or a circuit board; and
mounting the element onto the circuit board by using the mounting device according to claim 5 after the applying.

7. A method of manufacturing a circuit board device comprising:
mounting the element onto the circuit board by the mounting method according to claim 6; and
solidifying the adhesive after the mounting.
